(19) United States
(12) Patent Application Publication
(10) Pub. No.: US 2025/0277820 A1
(43) Pub. Date: Sep. 4, 2025

(54) COMPRESSED SENSING IN OSCILLOSCOPES FOR HIGHER BANDWIDTH

(71) Applicant: Tektronix, Inc., Beaverton, OR (US)

(72) Inventors: Andy K. Lim, Tigard, OR (US); Barton T. Hickman, Portland, OR (US); Shane L. Arnold, Beaverton, OR (US); Savitha Muthanna, Woodland Hills, CA (US)

(21) Appl. No.: 19/059,973

(22) Filed: Feb. 21, 2025

Related U.S. Application Data
(60) Provisional application No. 63/559,754, filed on Feb. 29, 2024.

(51) Int. Cl. G01R 13/02

(52) U.S. Cl. CPC G01R 13/0272; G01R 13/029

(57) ABSTRACT

A test and measurement instrument includes one or more ports to receive a signal from a device under test (DUT), an array of analog to digital converters (ADC) to receive the signal, a data collector to output one sample from each ADCs during one ADC clock cycle, and one or more processors to provide a sample clock to each ADC having a different clock phase from other ADCs to cause non-uniform sample spacing at or below a Nyquist frequency, and to cause the ADCs to output samples with non-uniform spacing. A method includes receiving a signal from a device under test, providing a sample clock to each ADC in an array of ADCs having a different clock phase from clock phases provided to other ADCs causing non-uniform sample spacing at or below a Nyquist frequency, sampling the signal with a non-uniform sample clock, and outputting the samples with non-uniform spacing.

### CROSS-REFERENCE TO RELATED APPLICATIONS

This disclosure is a non-provisional of and claims benefit from U.S. Provisional Application No. 63/559,754, titled “HIGH-BANDWIDTH OSCILLOSCOPE USING SUB-NYQUIST SAMPLING AND COMPRESSIVE SENSING,” filed on Feb. 29, 2024, the disclosure of which is incorporated herein by reference in its entirety.

### TECHNICAL FIELD

This disclosure relates to test and measurement instruments, and more particularly to test and measurement instruments that employ compressive sensing during sample acquisition.

### BACKGROUND

Generally, test and measurement instruments measure and test the operation and performance of devices under test (DUTs) by receiving signals from the DUT and then analyzing them. The signals typically comprise analog signals and need to undergo conversion by one or more analog-to-digital converters (ADCs).

Sampling an analog signal must occur at high enough frequency to avoid aliasing and signal distortion. Aliasing occurs when the instrument does not sample fast enough to reconstruct a signal accurately. The Nyquist or Nyquist-Shannon theorem states that the sampling frequency must at least twice the highest frequency component in the signal.

The requirement for high frequency sampling increases the complexity, and therefore, the cost of test and measurement instruments. In addition, the ever-increasing speed of signals requires instruments and methods that can handle the higher speeds.

### BRIEF DESCRIPTION OF DRAWINGS

FIG. 1 shows an embodiment of a test and measurement instrument.

FIG. 2 shows an embodiment of an array of analog-to-digital converters.

FIG. 3 shows a graphical representation of phases for analog-to-digital converters having non-uniform sample spacing.

FIG. 4 shows a flowchart of a method of sampling a signal using compressive sensing.

FIG. 5 shows a graphical representation of an embodiment of a method to reconstruct of a signal from compressive sensing samples.

FIG. 6 shows a graphical representation of an embodiment of a method to reconstruct a signal from compressive sensing samples.

### DESCRIPTION

Embodiments of the disclosure include test and measurement instruments, especially oscilloscopes, which employ compressive sensing (CS). CS allows the oscilloscopes to attain higher bandwidth than what can conventionally be achieved.

CS is fundamentally a L₁ minimization method to solve the problem for the under-determined system. Accordingly, CS allows recovery of the original signal from fewer samples than from Nyquist sampling.

Consider a classic problem in linear algebra:

$$y = Φ x \qquad ( 1 )$$

Equation 1 represent a critically determined system, meaning the number of equations is exactly equal to the number of unknowns. y is a column vector of size n. x is a column vector of size n. The symbol Φ represents an invertible n×n matrix. This is a classic n-equation, n-unknown problem. As an example, in Nyquist sampling, Φ is an identity matrix, and thus y=x. y is sampled measurements, and x is Nyquist bandlimited representation of the original signal. Suppose Φ is m×n dimension reduction matrix, where m<n.
x is a column vector of size n.
y is a column vector of size m.

The above set of equations is an ill-posed underdetermined system. Given measurement y and matrix Φ, the original signal x cannot be recovered.

However, this underdetermined system can be solved (with high probability) if x can be transformed into a k-sparse vector with k nonzero entries by a transform matrix Ψ, and that Φ is incoherent with respect to Ψ. Ψ for example, can be a Discrete Cosine Transform (DCT) matrix, a Discrete Fourier Transform (DFT) matrix, etc. Ψ is unitary and thus invertible. The nonzero entries are typically made up of significant enough values above some threshold, such as the noise floor. In such case, it is possible to solve for x with m measurements and y with L₁ minimization such that n>m≥2 k.

L₁ minimization can be achieved using various algorithms such as Matching Pursuit (MP), orthogonal matching pursuit (OMP), belief propagation (BP), . . . etc. The transforming x into a sparse vector s with Ψ matrix: s=Ψx. Equation (1) can be substituted with x=Ψ⁻¹s.

$$x = {Ψ}^{- 1} s \qquad ( 2 )$$

$$y = Φ {Ψ}^{- 1} s \qquad ( 3 )$$

By the associative property, A=ΦΨ⁻¹.

$$y = A s \qquad ( 4 )$$

y and A are known values, and by L₁ minimization, one can solve for s.

In addition, x=Ψ⁻¹s. The dimensions are Ψ is n×n, A is m×n, A is m×n.

For CS, conditions must be met to recover x from y. First, the vector x must be compressible, such that the vector x is k-sparse in some basis. For example, s=Ψx and s is k-sparse, where Ψ is a DCT or DFT.

Second, Φ must be incoherent with respect to Ψ. This means that the coherence, μ, of the matrices is μ(Φ, Ψ)=max_{1≤i≤m}max_{1≤j≤n}| [symbol] ΦᵢΨⱼ [symbol] |→1.0. A random matrix Φ nearly satisfies the conditional relationship above, but maybe not with absolute certainty. Φ is the independent and identically distributed (IID) random variable. Multiplying and IID matrix Φ with an orthonormal matrix, Ψ, is still and IID matrix. A matrix being orthonormal means that that columns form an orthonormal set in which each column has length one and is orthogonal to all the other column vectors.

Third, the matrix Φ should demonstrate the Restricted Isometry Property (RIP) in that the matrix Φ should behave almost orthonormal. In this case, due to the probability involved in CS the probability is high but not absolute that the columns are all length one and orthogonal to all the other columns, such that multiplication of a matrix with the matrix Φ is near isometry (distance preserving in L₂ minimization).

$$( 1 - {δ}_{k} ) {‖ s ‖}_{L 2}^{2} \leq {‖ Φ s ‖}_{L 2}^{2} \leq ( 1 + {δ}_{k} ) {‖ s ‖}_{L 2}^{2} \qquad ( 5 )$$

Equation 5 being true means Φ meets the k restricted isometry property with restricted isometry constant δₖ∈(0,1). A random matrix Φ, and k-sparse vector s, nearly satisfies this RIP condition meaning the probabilities are high that the matrix and vector meets the RIP condition. Although constructing RIP is np-hard, meaning that constructing RIP is one of the most challenging computational puzzles to solve, if Φ is random, RIP is satisfied with a high probability. The inability to meet it with absolute probability is why is nearly satisfies RIP. The randomness in Φ leads to incoherence which nearly satisfies the RIP.

Fourth, the condition

$$m \geq ck Log ( \frac{n}{k} )$$

must be met at some small constant, c>0 such that m≥2 k is true, for exact recovery. c is coherent between Ψ and Φ, and k approximates non-zero coefficients. Satisfying these requirements allows one to solve for s of Equation (4). Let s′=reconstructed version of s:

$${s}^{′} = min {‖ y - As ‖}_{1} \qquad ( 6 )$$

Here, the s is the sparse vector of x, which is the ideal Nyquist sample inferred (or imagined). If the minimization in Equation 6 is perfect, s=s′. Equation 6 can be solved using various iterative algorithms such as matching pursuit (MP), orthogonal matching pursuit (OMP), belief propagation (BP), etc.

Having defined terms used in compressive sensing as discussed here, the discussion now turns to how to employ compressive sensing in acquiring samples. Equation (3) provides the relationship y=ΦΨ⁻¹s, and Equation (2) provides the relationship x=Ψ⁻¹s. Without loss of generality, the variables are defined as:
x: n×1 signal sampled in the time domain at Nyquist rate
S: n×1 DCT transform of x in which is k-sparse in the frequency domain.
Ψ: n×n DCT transform matrix.
Φ: m×n measurement matrix.

Here, s is unknown. Ψ is simply the DCT of an identity matrix. The assumption of the present disclosure is that x is sparse in the frequency domain. In the implementation of the sampling scheme for CS, the measurement matrix Φ is the key component variable that the acquisition system must generate.

The measurement matrix Φ controls precisely the sample position in time. The y is the samples taken at those times. The Φ is m×n matrix. The dimension n is the length of the recovered acquisition sample record as if the acquisition were sampled at a Nyquist rate, and m is the number of samples taken that is fewer than n to recover the record. In the context of the discrete-time sampling, the matrix Φ is a binary matrix: coefficients are 1 or 0. The coefficient 1 indicates a sample, and 0 means no sample. There is exactly one sample per row. As an example, in classic Nyquist sampling, the Φ would be an n×n identity matrix.

The below discussion uses a 3×8 measurement matrix as an example:

$$Φ = \vert \begin{matrix}0 & 1 & 0 & 0 & 0 & 0 & 0 & 0 \\ 0 & 0 & 0 & 0 & 0 & 1 & 0 & 0 \\ 0 & 0 & 0 & 0 & 1 & 0 & 0 & 0\end{matrix} \vert$$

The resulting sample points are 0 1 0 0 1 0 1 1

The row order may be arbitrary. Each column represents a target Nyquist sample clock, meaning a clock that is sampling at two times the highest frequency component of the signal. The sparsity of the signal should determine the optimum dimension for Φ.

Given that the sample size, m≥ckLog (n/k), c≈3 to 5, with the lower being better, where c is the coherence value between Ψ and Φ. As an example, if n=1000, k=10, c≈4, then m≥184. Accordingly, this example results in Φ being targeted to more than 184 by 1000 columns. If m=200, then the number of samples acquired is 200/1000, which is 20% of a Nyquist sampling. The coefficients of the Φ are randomly generated such that Φ_{i,j}=1 at a random column j per row i. The randomness will more than likely satisfy the RIP requirement. Sorting the rows does not affect the results or the coherence.

In the context of a sample acquisition, m is the acquisition size, but with a non-uniform sample time spacing. Generally, the maximum average sample rate of the acquisition is fₛ. As discussed above, n is the length of the reconstructed record that is uniform in sample time. This achieves the sample rate of fₛ*(n/m).

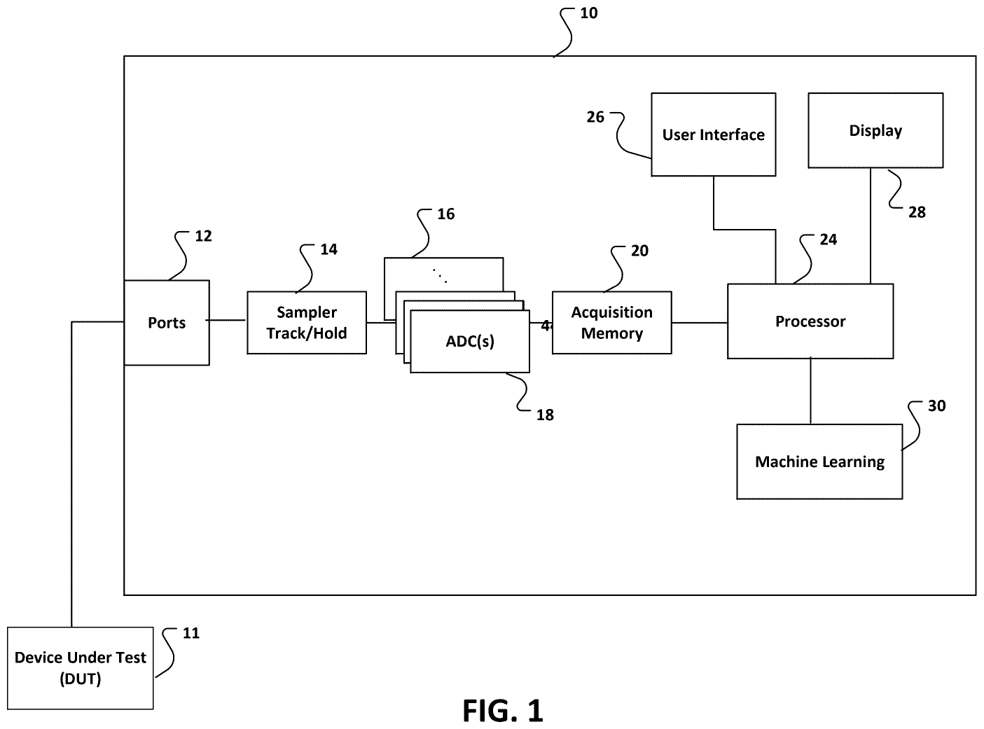

FIG. 1 shows a test and measurement instrument 10 such as an oscilloscope that can implement the above process based upon a signal received from a device under test (DUT) 11. FIG. 1 illustrates an example block diagram of a test and measurement instrument 10 according to some configurations of the disclosure. The test and measurement instrument 10 includes one or more ports 12, which may be any electrical signaling medium. Ports 12 may include receivers, transmitters, and/or transceivers. Each port 12 corresponds to a channel of the test and measurement instrument 10. The reference numbers of the components of the test and measurement instrument 10 will be referred to as needed in the figures that follow.

The signals from the ports 12 are then sent to a sampler track and hold circuit 14. The sampler track and hold circuit 14 holds each signal steady for a period of time sufficient to enable digitization by an array of analog-to-digital converters (ADCs) 18, made up of individual ADCs, such as ADC 16.

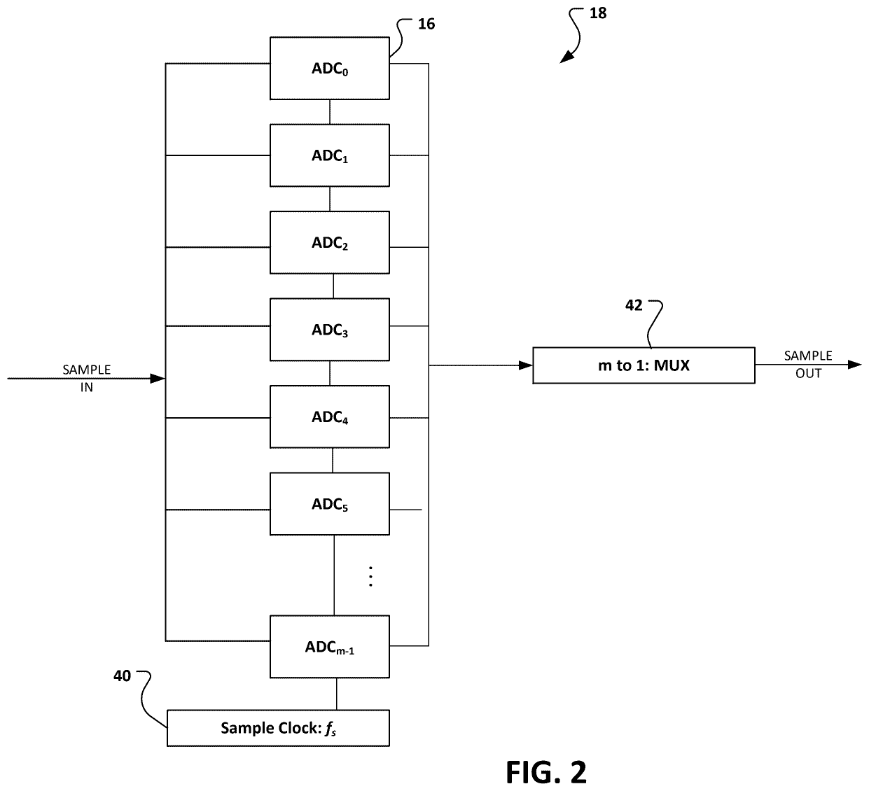

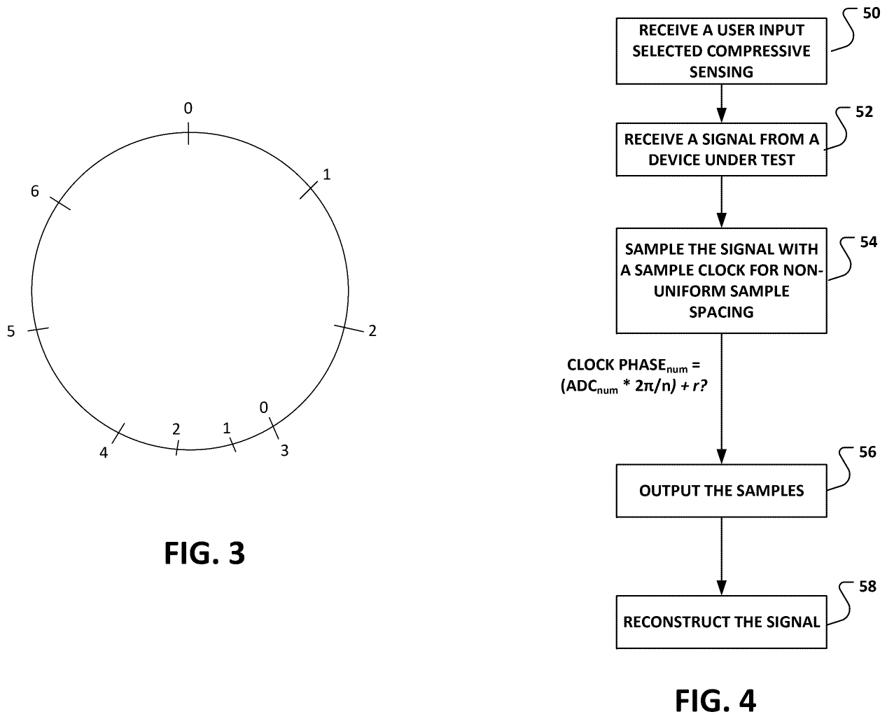

The array of ADCs 18 converts the analog signal from the sampler track and hold circuit 14 to a digital signal. As discussed in more detail regarding FIGS. 2 and 3, the array of ADCs 18, implement compressive sensing based upon the clock phase of each ADC 16 in the array of ADCs 18. The digitized signal from the array of ADCs 18 can then be stored in memory 20, which may comprise an acquisition memory and represents one or more memory structures in the instrument 10.

One or more processors 24 may be configured to execute instructions from memory 20 and may perform any methods and/or associated steps indicated by such instructions, such as receiving the acquired signals from the acquisition memory 20 and reconstructing the signal under test. The one or more processors 24 in some embodiments control the clock phase for each ADC 16 of the array of ADCs 18 to produce a non-uniform sampling time for the array of ADCs 18 with an ending sample frequency below the Nyquist frequency of the targeted bandwidth, which is higher than the Nyquist frequency of the array of ADCs 18 in the array of ADCs 18. This implements compressive sensing in the instrument.

Memory 20, which represents any memory in the test and measurement instrument 10, may be implemented as processor cache, random access memory (RAM), read only memory (ROM), solid state memory, hard disk drive(s), or any other memory type. Memory 20 acts as a medium for storing data, computer program products, and other instructions.

User interface 26 receives user inputs that are coupled to the one or more processors 24. User inputs may include a keyboard, mouse, trackball, touchscreen, and/or any other controls employable to allow a user to interact with a GUI on display 28. The display 28 may be a digital screen or any other monitor to display waveforms, measurements, and other data to a user. While the components of the test and measurement instrument 10 are depicted as being integrated within test and measurement instrument 10, it will be appreciated by a person of ordinary skill in the art that any of these components can be external to the test and measurement instrument 10 and can be coupled to the test and measurement instrument 10 in any conventional manner.

The resulting samples of the signal are sparse having been acquired by compressive sensing. The one or more processors 24 may execute code to reconstruct the signal from the sparse samples. As discussed in more detail further, reconstruction of the signal from the sparse samples may include the use of machine learning. The machine learning block 30 may take the form of code executed by the processors to perform machine learning processes or may comprise access to a separate machine learning system.

FIG. 2 show a more detailed view of an embodiment of an array of ADCs 18. The array of parallel ADCs 18 sample in non-uniform time. The one or more processors 24 can control the array of ADCs 18 with a specific phase to achieve sampling in non-uniform time. With an array of m ADCs 16, each ADC 16 samples at a maximum rate of fₛ using the sample clock 40. With m ADCs in the array of ADCs 18, each ADC 16 has a phase delay of 2π/m sampling the same input signal. This system comprises an interleaved system that samples at a rate of mfₛ. The multiplexer 42 outputs one sample at a time from each ADC 16 and does this for all m ADCs 16 in a single ADC clock cycle, outputting m samples each ADC clock cycle. Alternatively, a first-in-first-out (FIFO) buffer could replace the multiplexer 42. The FIFO would accumulate the m samples and outputs the m sample every clock. The component that outputs the m samples in one ADC clock cycle will be referred to here as a “data collector.” The data collector may comprise a multiplexer or a FIFO, as examples.

In another embodiment, the random sample clock arrangement may be employed by the m ADCs 16 in the array of ADCs 18, but the number of desired samples is some multiple of the number of ADCs, m. The one or more processors 24 would execute code to provide a sample clock so that each ADC samples iteratively a number of times to achieve the desired number of samples. Each clock for each ADC 16 for each iteration may have a different phase.

In the interleaved system, the phase is delayed [0,2π) in linear increments of 2π/m for ADC₀ to ADC₍ₘ₋₁₎. The phase delay step size is Δθ=2π/m, but for the CS system, instead of using Δθ=2π/m, the system uses Δθ=2π/(mM), where M=n/m, Δθ=2π/n. Therefore, the sample spacing is smaller and the resolvable bandwidth is increased by a factor of M, but the total number of samples acquired is m. Therefore, the average sample rate is still mfₛ, and not Mmfₛ.

The formulation for an interleaved system uses the following definitions. The ratio of the target Nyquist sample rate over the hardware Nyquist sample rates is M=n/m. The uniform, time-interleaved sample rate, fᵢₗᵥ, for m ADCs equals mfₛ. This makes the uniform, time-interleaved sample period Tᵢₗᵥ=1/fᵢₗᵥ. The target sample spacing is T_{CS}=Tᵢₗᵥ/M, and the target sample rate, f_{CS}=1/T_{CS}. The average sample spacing, T_{avg}=M*T_{CS}=Tᵢₗᵥ. Here, T_{arg} will always equal Tᵢₗᵥ.

To achieve non-uniform sample spacing, T[i] is set equal to rT_{CS}, where r is an integer random variable with a flat distribution ranging from 0 to M−1. As a result the sampling time then becomes t[i]=iT_{avg}+T[i]. This sampling time satisfies the measurement matrix Φ with the conditions required for CS.

FIG. 3 shows a graphical representation of the phase angles for each ADC. In the example, there are m=7 ADCs, and the ADCs are numbered 0 to 6. The ratio of the target Nyquist rate over the hardware sample rate is 3, so the CS system takes 7 samples for every 21 of a Nyquist system. Each ADC is at 51 degrees of phase, 0, 51, 102, 153, 204, 255, and 306, each position shown by the ADC numbers 0-6 in the diagram. The 51 degrees between each ADC phase position is divided into M segments, in this example 3. The phase of each ADC is then its phase position plus a random number between 0-2, where the random number is generated each phase position.

Therefore, each ADC takes on a phase angle of (0, 1, or 2)*2π/n degrees, shown by the numbered positions in the diagram, or approximately 51 degrees. Each ADC phase is then adjusted by the multiplier r of 0, 1, or 2, each r is 17 degrees. The adjustment of each phase leads to ADC₀ phase=0+((0, 1, or 2)*17 deg)), ADC₁ phase=51+((0, 1, or 2)*17 deg)), ADC₂ phase=102+((0, 1, or 2)*17 deg), until ADC₆ phase=(51*6)+((0, 1, or 2)*17 deg).

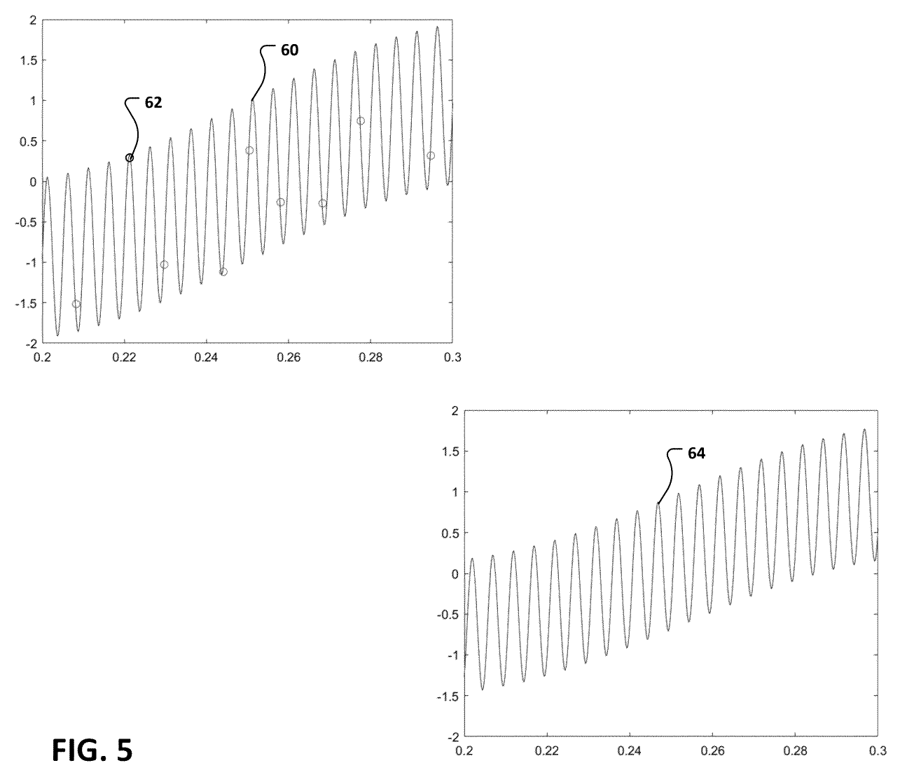

In summary, the process uses non-uniform sampling to implement compressive sensing. FIG. 4 shows a flow chart of an embodiment of a method of compressing sensing. The user interface 26 on the instrument 10 may provide the user the selection to perform compressive sensing and bypass the higher Nyquist rate. The user may make that decision based upon the user's knowledge of the signal. Alternatively, the instrument may exist as a compressive sensing instrument, rather than being selectable between compressive and conventional sensing. The step 50 in FIG. 4 is therefore optional.

At 52, the instrument 10 receives a signal from a DUT, such as DUT 11 of FIG. 1. The instrument 10 then provides a sample clock for non-uniform sample spacing. As discussed above, this may involve an array of ADCs 18, each having ADCs having a clock phase position of the number of the ADC multiplied by 2π/n and then adjusted by some subset of the phase divisions multiplied by r. The instrument 10 then outputs the samples generated from the compressive sensing array of ADCs 18 for further analysis. In some embodiments, the instrument 10, using the one or more processors 24, may reconstruct the signal using one of several different options.

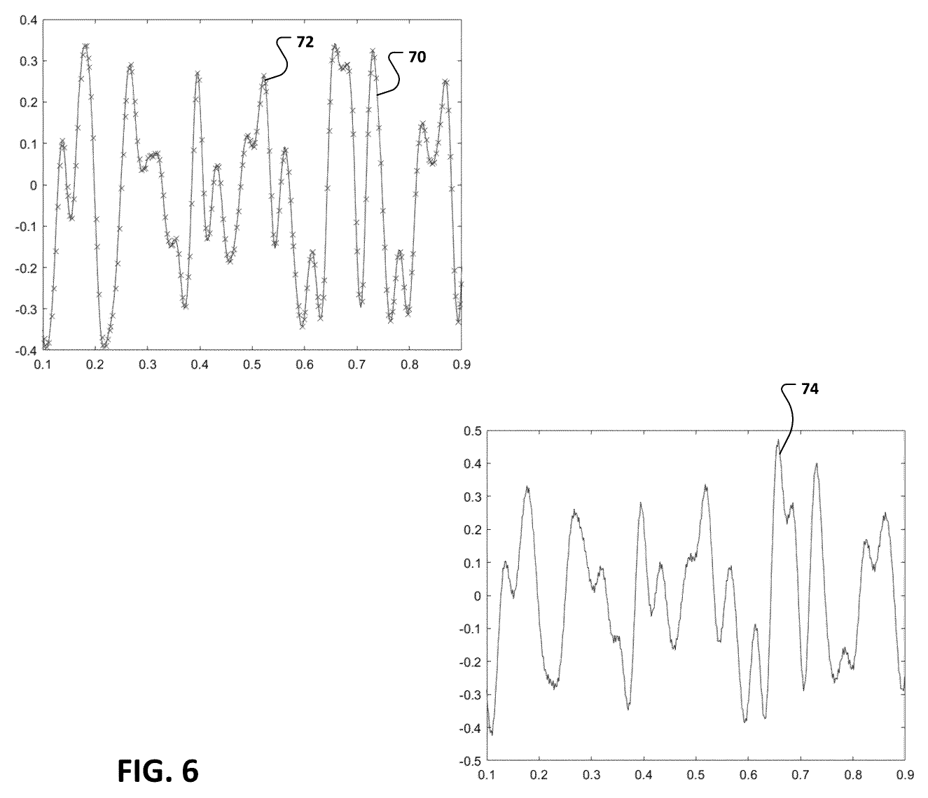

FIG. 5 shows an original modulated waveform 60. The circles 62 show the sample points. In this example, there are 42 times fewer samples than the Nyquist requirement. The lower right waveform 64 is the reconstructed waveform using the simplest Matching Pursuit algorithm. FIG. 6 shows a similar comparison for a Pulse-Amplitude Modulated 4 (PAM4), short stress pattern random quaternary (SSPRQ) waveform 70. The samples are taken at the ‘x’ spots 72. In this example, there are two times fewer samples. The reconstructed waveform 74 is shown on the lower right, also obtained with a Matching Pursuit algorithm.

Many other types of reconstruction algorithm may be used to reconstruct the compressively sensed signals. These may include convex optimization schemes, in machine learning, like gradient descent, projected gradient, and Quasi-Newton methods. Other possibilities include interior point methods using convex conjugate gradients and barrier functions, as some of the reconstruction methods that could be used, instead of match pursuit or basis pursuit, which are grouped together in this discussion as best matching nonlinear approximations of the signal. Another option is a cuda-based parallel processing technique that is commonly employed with such techniques to solve the L₁ minimization problem that exists in compressive sensing.

Some approaches may be referred to as gradient approaches. An example is gradient methods using derivatives: One of the approaches to convex optimization is via first computing the convex function's gradient, then using this derivative for performing convex optimization. Projected gradient methods: This convex optimization approach was first introduced for solving convex problems with convex objective functions and convex constraints. It has an advantage over gradient methods using derivatives, if the system of convex constraints is not satisfied at the current iterate, it simply projects onto the subspace defined by these convex constraints.

Other approaches may include Quasi-Newton methods. These methods are based on approximating the Hessian matrix of second derivatives by a quadratic approximation (where any convex function such as a linear one, can be used). The convex problem with convex constraints is solved using the quasi-Newton method to converge faster. It employs both first and second derivatives of convex objective functions to iteratively compute convex function minima using only function evaluations. The algorithm uses quadratic approximations around convex minimization iterations, thus requiring only function evaluations. An initial point is required to start convex optimization.

Yet even more approaches include interior point methods using convex conjugate gradients and barrier function: If convexity is easy to check and convex function is twice differentiable, then the barrier function convex conjugate gradient method can be used to solve convex optimization problems. The two methods combined also make it easier to avoid going into a local minimum—there is a gradient test before each iteration that checks if the step would go towards a local minimum. Global convex minimization: For convex problems, the quasi-Newton method usually gives better convergence results when compared with other techniques such as the gradient-based methods and the barrier function convex conjugate gradient method. However, this might not always be the case, there might be convex problems where the quasi-Newton method converges slowly or even in a non-convergent manner. In such cases, an alternative approach is to use a global convex minimization technique instead of a local convex minimization technique.

More conventional machine learning approaches could be used, such as training a model with data sets comprised of a compressively sensed frequency spectrum of the signal, or other signal shapes, and the original waveform. This would train the model to recognize the compressively sensed signal and provide the reconstructed signal.

In this manner, a test and measurement instrument can compressively sense signals, resulting in speed gains and hardware savings.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.
Example 1 is a test and measurement instrument, comprising: one or more ports to connect to a device under test (DUT) and receive a signal from the DUT; an array of analog to digital converters (ADC) to receive the signal in parallel; a data collector to select each ADC from the array of ADC to cause the array to output one sample from each of the ADCs in the array of ADCs during one ADC clock cycle; and one or more processors configured to execute code that causes the one or more processors to provide a sample clock to each ADC in the array of ADCs having a different clock phase from other ADCs in the array of ADCs cause non-uniform sample spacing at below a Nyquist frequency to cause the ADCs to output samples with non-uniform sample spacing.
Example 2 is the test and measurement instrument of Example 1, wherein the code that causes the one or more processors to provide the sample clock having the different clock phase to each ADC in the array of ADCs comprises code that causes the one or more processors to: divide 2x by m, where m is a number of ADCs in the array of ADCs to produce an initial clock phase for each ADC; divide the initial clock phase of each ADC into a number of steps equal to M, where M is ratio of a Nyquist sample rate divided by a hardware sample rate; and randomly select a step, r, from the number of steps for each ADC and adding the step to the initial clock phase for each ADC to produce the clock phase for each ADC.
Example 3 is the test and measurement instrument of Example 2, wherein the ratio of the Nyquist sample rate over a hardware sample rate, M, multiplied by the number of ADCs in the array equals the Nyquist sample rate.
Example 4 is the test and measurement instrument of any of Examples 1 through 3, wherein: a desired number of samples is a multiple of the number of ADCs in the array of ADCs; and the code that causes the one or more processors to provide the sample clock comprises code to provide the sample clock so each ADC in the array of ADCs iteratively samples a number of times to obtain the desired number of samples, each iteration of each ADC having a different clock phase.
Example 5 is the test and measurement instrument of any of Examples 1 through 4, wherein the one or more processors are further configured to execute code to reconstruct the signal from the samples with non-uniform sample spacing at below the Nyquist frequency.
Example 6 is the test and measurement instrument of Example 5, wherein the code that causes the one or more processors to reconstruct the signal comprises code that causes the one or more processors to compute a best matching nonlinear approximation to the signal.
Example 7 is the test and measurement instrument of Example 5, wherein the code that causes the one or more processors to reconstruct the signal comprise code that causes the one or more processors to use a trained machine learning system to reconstruct the signal based upon a shape of a waveform of the signal.
Example 8 is the test and measurement instrument of Example 5, wherein the code that causes the one or more processors to reconstruct the signal comprises code that causes the one or more processor to perform one of a gradient descent, projected gradient, Quasi-Newton, or interior point processes.
Example 9 is the test and measurement instrument of any of Examples 1 through 8, wherein the one or more processors are further configured to execute code to cause the one or more processors to present an option for compressive sensing to a user on a user interface of the instrument.
Example 10 is a method to compressively sense a signal from a device under test (DUT), comprising: receiving the signal from the DUT; providing a sample clock to each ADC in an array of ADCs having a different clock phase from clock phases provided to other ADCs in the array of ADCs causing non-uniform sample spacing at below a Nyquist frequency; sampling the signal with a non-uniform sample clock; and outputting the samples with non-uniform sample spacing for further analysis.
Example 11 is the method of Example 10, wherein providing the sample clock having a different clock phase to each ADC comprises: dividing 2x by m, where m is a number of ADCs in the array of ADCs to produce an initial clock phase for each ADC; dividing the initial clock phase of each ADC into a number of steps equal to M, where M is a ratio of a Nyquist sample rate divided by a hardware sample rate; and randomly selecting a step, r, from the number of steps for each ADC and adding the step to the initial clock phase for each ADC to produce a respective clock phase for each ADC.
Example 12 is the method of either of Examples 10 or 11, wherein the ratio of the Nyquist sample rate over the hardware rate, M, multiplied by the number of ADCs in the array of ADCs equals the Nyquist sample rate.
Example 13 is the method of Example 12, wherein providing the sample clock to each ADC in the array of ADCs comprises: defining a desired number of samples equals a multiple of the number of ADCs in the array of ADCs; and obtaining the desired number of samples by having each ADC in the array of ADCs iteratively sampling a number of times, each iteration of each ADC having a different clock phase.
Example 14 is the method of any of Examples 11 through 13, further comprising reconstructing the signal from the samples with non-uniform sample spacing at below the Nyquist frequency.
Example 15 is the method of Example 14, wherein reconstructing the signal comprises computing a best matching nonlinear approximation to the signal.
Example 16 is the method of Example 14, wherein reconstructing the signal comprises using a trained machine learning system to reconstruct the signal based upon a frequency domain version of the signal.
Example 17 is the method of Example 14, wherein reconstructing the signal comprises performing one of a gradient descent, projected gradient, Quasi-Newton, or interior point processes.
Example 18 is the method of any of Examples 11 through 17, further comprising presenting an option for compressive sensing to a user on a user interface of an instrument.
Example 19 is an array of analog-to-digital-converters (ADCs) for random sampling of a signal, comprising: an array of analog to digital converters (ADC) arranged to receive the signal in parallel; a data collector to select each ADC from the array of ADC to cause the array to output one sample per ADC per clock cycle; and a sample clock connected to each ADC in the array of ADCs, each ADC having a different clock phase from other ADCs in the array of ADCs to cause non-uniform sample spacing at below a Nyquist frequency.
Example 20 is the array of analog-to-digital converters of Example 19, wherein the data collector comprises one of either a multiplexer or a first-in-first-out buffer.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to connect to a device under test (DUT) and receive a signal from the DUT;
an array of analog to digital converters (ADC) to receive the signal in parallel;
a data collector to select each ADC from the array of ADCs to cause the array to output one sample from each of the ADCs in the array of ADCs during one ADC clock cycle; and
one or more processors configured to execute code that causes the one or more processors to provide a sample clock to each ADC in the array of ADCs having a different clock phase from other ADCs in the array of ADCs to cause non-uniform sample spacing at below a Nyquist frequency, and to cause the ADCs to output samples with non-uniform sample spacing.

2. The test and measurement instrument as claimed in claim 1, wherein the code that causes the one or more processors to provide the sample clock having the different clock phase to each ADC in the array of ADCs comprises code that causes the one or more processors to:
divide 2π by m, where m is a number of ADCs in the array of ADCs to produce an initial clock phase for each ADC;
divide the initial clock phase of each ADC into a number of steps equal to M, where M is ratio of a Nyquist sample rate divided by a hardware sample rate; and
randomly select a step, r, from the number of steps for each ADC and adding the step to the initial clock phase for each ADC to produce the clock phase for each ADC.

3. The test and measurement instrument as claimed in claim 2, wherein the ratio of the Nyquist sample rate over a hardware sample rate, M, multiplied by the number of ADCs in the array equals the Nyquist sample rate.

4. The test and measurement instrument as claimed in claim 1, wherein:
a desired number of samples is a multiple of the number of ADCs in the array of ADCs; and
the code that causes the one or more processors to provide the sample clock comprises code to provide the sample clock so each ADC in the array of ADCs iteratively samples a number of times to obtain the desired number of samples, each iteration of each ADC having a different clock phase.

5. The test and measurement instrument as claimed in claim 1, wherein the one or more processors are further configured to execute code to reconstruct the signal from the samples with non-uniform sample spacing at below the Nyquist frequency.

6. The test and measurement instrument as claimed in claim 5, wherein the code that causes the one or more processors to reconstruct the signal comprises code that causes the one or more processors to compute a best matching nonlinear approximation to the signal.

7. The test and measurement instrument as claimed in claim 5, wherein the code that causes the one or more processors to reconstruct the signal comprise code that causes the one or more processors to use a trained machine learning system to reconstruct the signal based upon a shape of a waveform of the signal.

8. The test and measurement instrument as claimed in claim 5, wherein the code that causes the one or more processors to reconstruct the signal comprises code that causes the one or more processor to perform one of a gradient descent, projected gradient, Quasi-Newton, or interior point processes.

9. The test and measurement instrument as claimed in claim 1, wherein the one or more processors are further configured to execute code to cause the one or more processors to present an option for compressive sensing to a user on a user interface of the instrument.

10. A method to compressively sense a signal from a device under test (DUT), comprising:
receiving the signal from the DUT;
providing a sample clock to each ADC in an array of ADCs having a different clock phase from clock phases provided to other ADCs in the array of ADCs causing non-uniform sample spacing at below a Nyquist frequency;
sampling the signal with a non-uniform sample clock; and
outputting the samples with non-uniform sample spacing for further analysis.

11. The method as claimed in claim 10, wherein providing the sample clock having a different clock phase to each ADC comprises:
dividing 2π by m, where m is a number of ADCs in the array of ADCs to produce an initial clock phase for each ADC;
dividing the initial clock phase of each ADC into a number of steps equal to M, where M is a ratio of a Nyquist sample rate divided by a hardware sample rate; and
randomly selecting a step, r, from the number of steps for each ADC and adding the step to the initial clock phase for each ADC to produce a respective clock phase for each ADC.

12. The method as claimed in claim 11, wherein the ratio of the Nyquist sample rate over the hardware rate, M, multiplied by the number of ADCs in the array of ADCs equals the Nyquist sample rate.

13. The method as claimed in claim 12, wherein providing the sample clock to each ADC in the array of ADCs comprises:
defining a desired number of samples equals a multiple of the number of ADCs in the array of ADCs; and
obtaining the desired number of samples by having each ADC in the array of ADCs iteratively sampling a number of times, each iteration of each ADC having a different clock phase.

14. The method as claimed in claim 10, further comprising reconstructing the signal from the samples with non-uniform sample spacing at below the Nyquist frequency.

15. The method as claimed in claim 14, wherein reconstructing the signal comprises computing a best matching nonlinear approximation to the signal.

16. The method as claimed in claim 14, wherein reconstructing the signal comprises using a trained machine learning system to reconstruct the signal based upon a frequency domain version of the signal.

17. The method as claimed in claim 14, wherein reconstructing the signal comprises performing one of a gradient descent, projected gradient, Quasi-Newton, or interior point processes.

18. The method as claimed in claim 10, further comprising presenting an option for compressive sensing to a user on a user interface of an instrument.

19. An array of analog-to-digital-converters (ADCs) for random sampling of a signal, comprising:
an array of analog to digital converters (ADC) arranged to receive the signal in parallel;
a data collector to select each ADC from the array of ADC to cause the array to output one sample per ADC per clock cycle; and
a sample clock connected to each ADC in the array of ADCs, each ADC having a different clock phase from other ADCs in the array of ADCs to cause non-uniform sample spacing at below a Nyquist frequency.

20. The array of analog-to-digital converters as claimed in claim 19, wherein the data collector comprises one of either a multiplexer or a first-in-first-out buffer.
